(19) United States
(12) Patent Application Publication
(10) Pub. No.: US 2019/0229014 A1
(43) Pub. Date: Jul. 25, 2019

(54) METHOD FOR FABRICATING A SEMICONDUCTOR STRUCTURE

(71) Applicants: UNITED MICROELECTRONICS CORP., Hsin-Chu City (TW); Fujian Jinhua Integrated Circuit Co., Ltd., Quanzhou City (CN)

(72) Inventors: Kuan-Chun Lin, Tainan City (TW); Hsin-Fu Huang, Tainan City (TW); Wei-Chih Chen, Tainan City (TW)

(21) Appl. No.: 15/888,069

(22) Filed: Feb. 4, 2018

(30) Foreign Application Priority Data
Jan. 25, 2018 (CN) 201810072028.4

(51) Int. Cl. H01L 21/768; H01L 21/02; H01L 23/532; H01L 23/522

(52) U.S. Cl. CPC H01L 21/76834; H01L 21/0217; H01L 21/02266; H01L 27/1052; H01L 23/53266; H01L 23/53271; H01L 23/5226; H01L 23/5329

(57) ABSTRACT

A method for fabricating a semiconductor structure is disclosed. A bit line is formed on a substrate. The bit line comprises a tungsten layer and cap layer on the tungsten layer. A low-temperature physical vapor deposition (PVD) process is performed to deposit a silicon nitride spacer layer covering the bit line and the substrate. The silicon nitride spacer layer is in direct contact with the tungsten layer. The low-temperature PVD process is performed at a temperature ranging between 200˜400° C.

### BACKGROUND OF THE INVENTION

### 1. Field of the Invention

The present invention relates to a semiconductor structure and a method of forming the same, and more particularly to a bit line structure of a memory and a method of forming the same.

### 2. Description of the Prior Art

As the integration of non-volatile memory increases, the bit line width of memory must also be reduced. However, the decrease of the bit line width leads to an increase of the resistance value, so that the current of the memory cell becomes smaller, leading to an excessively high bit line loading. This shows that the bit line resistance of the memory is very important for the operation efficiency of the memory.

In general, the memory bit line includes a stacked structure of multi-layered material films. For example, a tungsten layer is disposed on the polysilicon layer, and then a silicon nitride capping layer is disposed on the tungsten layer. After the etching of the stacked structure is completed, a silicon nitride sidewall spacer layer is deposited on the stacked structure by a chemical vapor deposition (CVD) process. However, in the high-temperature environment of the CVD process, the nitrogen will react with the tungsten layer in the stacked structure to form tungsten nitride on its sidewalls, resulting in an increase in the resistance of the bit line of the memory.

Therefore, there is still a need in the art for an improved bit line structure of a memory and a method for forming the same, so as to solve the shortcomings and disadvantages of the prior art.

### SUMMARY OF THE INVENTION

It is one object of the present invention to provide a method for fabricating a semiconductor structure, which can solve the shortcomings and disadvantages of the prior art.

One embodiment of the invention discloses a method for fabricating a semiconductor structure. First, a substrate is provided. A bit line is then formed on the substrate. The bit line comprises a tungsten layer and cap layer on the tungsten layer. A low-temperature physical vapor deposition (PVD) process is performed to deposit a silicon nitride spacer layer covering the bit line and the substrate. The silicon nitride spacer layer is in direct contact with the tungsten layer. The low-temperature PVD process is performed at a temperature ranging between 200˜400° C.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 and FIG. 2 are schematic, cross-sectional views illustrating a method for fabricating a semiconductor structure according to an embodiment of the present invention.

### DETAILED DESCRIPTION

In the following, the details will be described with reference to the drawings, the contents of which also form part of the description of the specification and are illustrated in the specific examples in which the embodiment can be practiced. The following examples have described sufficient details to enable those of ordinary skill in the art to practice this invention.

Of course, other embodiments may be adopted, or any structural, logical, and electrical changes may be made without departing from the embodiments described herein. Therefore, the following detailed description is not to be taken in a limiting sense, and the examples contained therein are to be defined by the appended claims.

The present invention pertains to a method for manufacturing a semiconductor structure, for example, a bit line of a memory having a low resistance.

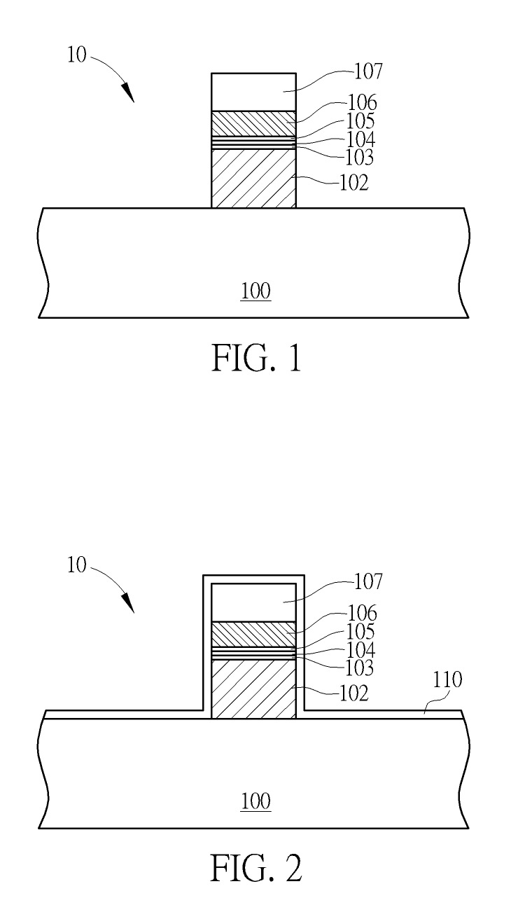

Please refer to FIG. 1 and FIG. 2, which are schematic, cross-sectional views of a method for fabricating a semiconductor structure according to one embodiment of the present invention. As shown in FIG. 1, a substrate 100, for example, a silicon substrate, is provided. A bit line 10 is formed on the substrate 100. According to an embodiment of the present invention, the bit line 10 is a stacked structure of multi-layered material films, and includes, in the order of from bottom to the top, a polysilicon layer 102, a titanium layer 103, a titanium nitride (TiN) layer 104, a tungsten silicide (WSi) layer 105, a tungsten layer 106 and a cap layer 107.

According to an embodiment of the present invention, the cap layer 107 is located on the tungsten layer 106 and is in direct contact with the tungsten layer 106. According to an embodiment of the present invention, the cap layer 107 includes a silicon nitride layer.

According to an embodiment of the present invention, the polysilicon layer 102 is interposed between the substrate 100 and the tungsten layer 106. The titanium layer 103 is interposed between the polysilicon layer 102 and the tungsten layer 106. The titanium nitride layer 104 is interposed between the titanium layer 103 and the tungsten layer 106. The tungsten silicide layer 105 is interposed between the titanium nitride layer 104 and the tungsten layer 106.

As shown in FIG. 2, a low-temperature physical vapor deposition (PVD) process is performed to conformally deposit a silicon nitride sidewall spacer layer 110 along the surface of the bit line 10 and the surface of the substrate 100. According to an embodiment of the present invention, the silicon nitride sidewall spacer layer 110 directly contacts the tungsten layer 106.

According to an embodiment of the present invention, the low temperature PVD process is performed at 200 to 400° C. The PVD process performed at this relatively low temperature does not cause nitrogen to react with the tungsten layer of the stacked structure to form tungsten nitride on the sidewall of the bit line so that the resistance is lower.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a semiconductor structure, comprising:
providing a substrate;
forming a bit line on the substrate, wherein the bit line comprises a tungsten layer and cap layer on the tungsten layer; and
performing a low-temperature physical vapor deposition (PVD) process to deposit a silicon nitride spacer layer covering the bit line and the substrate, wherein the silicon nitride spacer layer is in direct contact with the tungsten layer.

2. The method according to claim 1, wherein the bit line further comprises a polysilicon layer between the substrate and the tungsten layer.

3. The method according to claim 2, wherein the bit line further comprises a titanium layer between the polysilicon layer and the tungsten layer.

4. The method according to claim 3, wherein the bit line further comprises a titanium nitride layer between the titanium layer and the tungsten layer.

5. The method according to claim 4, wherein the bit line further comprises a tungsten nitride layer between the titanium nitride layer and the tungsten layer.

6. The method according to claim 1, wherein the cap layer comprises a silicon nitride layer.

7. The method according to claim 1, wherein the low-temperature PVD process is performed at a temperature ranging between 200˜400° C.

8. A semiconductor structure fabricated by the method according to any of claims 1 to 7.
